(19) United States
(12) Patent Application Publication
(10) Pub. No.: US 2012/0044411 A1
(43) Pub. Date: Feb. 23, 2012

(54) CAMERA MODULE AND METHOD FOR ASSEMBLING THE SAME

(75) Inventors: WEN-CHIH WANG, Tu-Cheng (TW); SHIH-MIN LO, Tu-Cheng (TW)

(73) Assignee: HON HAI PRECISION INDUSTRY CO., LTD., Tu-Cheng (TW)

(21) Appl. No.: 12/978,551

(22) Filed: Dec. 25, 2010

(30) Foreign Application Priority Data
Aug. 19, 2010 (TW) 99127653

(51) Int. Cl. H04N 5/225; H05K 13/00

(52) U.S. Cl. 348/374; 29/592.1; 348/E05.024

(57) ABSTRACT

A camera module includes a first circuit board, a holder, a lens module, an image sensor chip, a filter, and a second circuit board. The holder includes a sleeve and a base connected to an end of the sleeve. The lens module is received in the sleeve. The holder is mounted on the first circuit board. The base defines a first receiving portion. The image sensor chip is electrically fixed to the first circuit board and received in the first receiving portion. The filter is received in the first receiving portion corresponding to the image sensor chip. The second circuit board is electrically connected to the first circuit board. The second circuit board is received in the first receiving portion and fixed to the base.

### BACKGROUND

1. Technical Field

The present disclosure relates to image capture, and more particularly, to a camera module for an electronic device and a method for assembling the same.

2. Description of Related Art

Camera modules are widely used in electronic devices such as personal digital assistants, mobile phones, portable computers and others.

A typical cameral module includes a circuit board, a holder, a lens module, an image sensor chip, and a filter. The holder includes a sleeve and a base connected to an end of the sleeve. The lens module is received in the sleeve. The holder is mounted on the circuit board. The base is a hollow chamber. The image sensor chip is electrically fixed to the first circuit board and received on base. The filter is received in the base corresponding to the image sensor chip. Incident light is capable of passing through the lens module and the filter in that order, and finally projecting on the image sensor. The camera module further includes a plurality of electronic elements and integrated circuits disposed on the circuit board.

However, a distribution density of the electronic elements and the integrated circuits on the circuit board is very high such that the circuit board must be large, and as a result, the volume of the camera module is large.

Therefore, there is room for improvement within the art.

### BRIEF DESCRIPTION OF THE DRAWINGS

The components in the drawings are not necessarily drawn to scale, the emphasis instead being positioned upon clearly illustrating the principles of the present disclosure. Moreover, in the drawings, like reference numerals designate corresponding parts throughout the views.

FIG. 1 is cross section of a first embodiment of a camera module.

FIG. 2 is cross section of a second embodiment of a camera module.

FIG. 3 is a flowchart of a method for assembling the camera module of FIG. 1.

### DETAILED DESCRIPTION

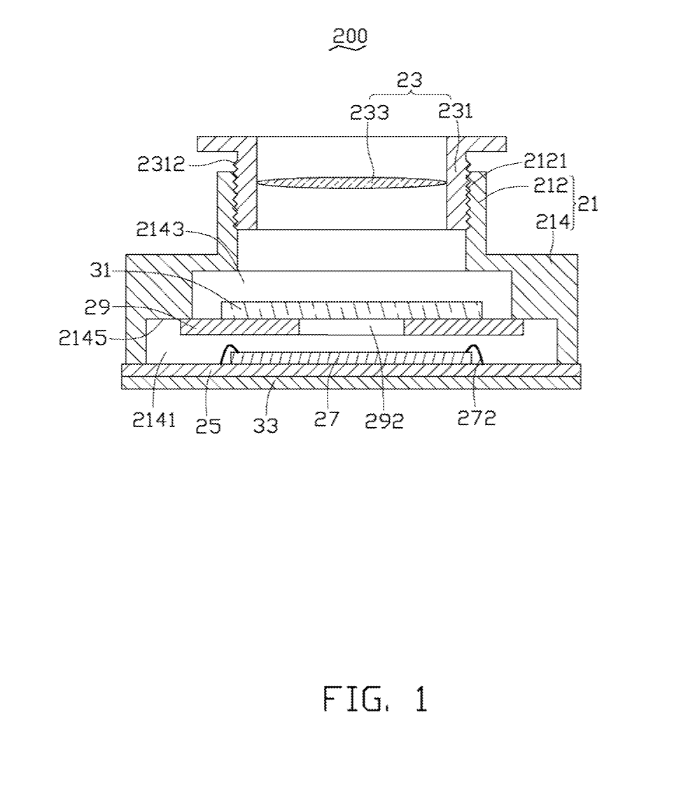

Referring to FIG. 1, a first embodiment of a camera module 200 includes a holder 21, a lens module 23, a first circuit board 25, an image sensor chip 27, a second circuit board 29, and a filter 31. The lens module 23 is partially received in the holder 21. The holder 21 is mounted on the first circuit board 25. The image sensor chip 27, the second circuit board 29, and the filter 31 are received in the holder 21.

The holder 21 includes a sleeve 212 and a base 214 connected to an end of the sleeve 212. The sleeve 212 is a substantially hollow cylinder, and forms an internal thread 2121 on an inner surface of the sleeve 212. The base 214 is substantially rectangular, and defines a first receiving portion 2141 and a second receiving portion 2143. The first receiving portion 2141 is a substantially rectangular groove depressed from an end of the base 214 away from the sleeve 212. The second receiving portion 2143 is a substantially rectangular groove depressed from a bottom of the first receiving portion 2141. A width of the second receiving portion 2143 is less than that of the first receiving portion 2141, therefore a fixing surface 2145 is defined on the bottom of the first receiving portion 2141 adjacent to the second receiving portion 2143. The second receiving portion 2143 is defined between the sleeve 212 and the first receiving portion 2141 and communicates with the sleeve 212 and the first receiving portion 2141.

The lens module 23 includes a lens barrel 231 and at least one lens 233 received therein. The lens barrel 231 forms an external thread 2312 on an outer surface of the lens barrel 231. The lens module 23 is threaded into the sleeve 212 of the holder 21 by the external thread 2312 of the lens barrel 231 threading on the internal thread 2121 of the sleeve 212.

The first circuit board 25 is fixed to a distal end of the base 214 away from the sleeve 212, such that the first circuit board 25, the lens module 23, and the base 21 cooperatively define an interspace. The first circuit board 25 may be a rigid printed circuit board, a flexible printed circuit board, or a rigid flex printed circuit board. The image sensor chip 27 is received in the first receiving portion 2141 and electrically fixed to a middle portion of the first circuit board 25 by wires 272 corresponding to the lens 233. The image sensor chip 27 may be a charge coupled device (CCD) or a complementary metal oxide semiconductor (CMOS).

The second circuit board 29 is smaller than the first circuit board 25. The second circuit board 29 is fixed to the fixing surface 2145 of the base 21 in the first receiving portion 2141. The second circuit board 29 defines a light through hole 292 in the middle portion thereof corresponding to the lens 233. The second circuit board 29 may also be a rigid printed circuit board, a flexible printed circuit board, or a rigid flex printed circuit board. In the illustrated embodiment, the holder 21 is metal, and the first circuit board 25 and the second circuit board 29 are fixed to the holder 21 by conductive adhesive (not shown). It should be pointed out that the first circuit board 25 and the second circuit board 29 may be fixed to the holder 21 by three-dimensional electroplating or welding.

The filter 31 is fixed to the second circuit board 29 and shields the light through hole 292. Incident light is capable of passing through the lens 233 of the lens module 23 and the filter 31 in that order, and finally projecting on the image sensor chip 27. In the illustrated embodiment, the filter 31 is positioned at a side of the second circuit board 29 away from the first circuit board 25. The camera module 200 further includes a plurality of electronic elements and integrated circuits (not shown) selectively disposed on the first circuit board 27 or the second circuit board 29. It should be pointed out that the filter 31 may be fixed to the holder 21 directly and received in the second receiving portion 2143, as long as the filter 31 corresponds to the image sensor chip 27 and the lens 233.

The camera module 200 further includes a substrate 33 attached to a side surface of the first circuit board 25 away from the holder 21 to support the first circuit board 25.

The electronic elements and integrated circuits of the camera module 200 may be selectively disposed on the first circuit board 27 or on the second circuit board 29, thus the camera module 200 has a compact configuration with a relatively low distribution density of the electronic elements and integrated circuits, and can be easily manufactured.

Alternatively, the second circuit board 29 may be received in the first receiving portion 2141 and fixed to the holder 21, as long as the second circuit board 29 is offset against the image sensor chip 27. The second receiving portion 2143 may further be omitted, whereby the second circuit board 29 is fixed to the fixing surface 2145, and the filter 31 is received in the sleeve 212.

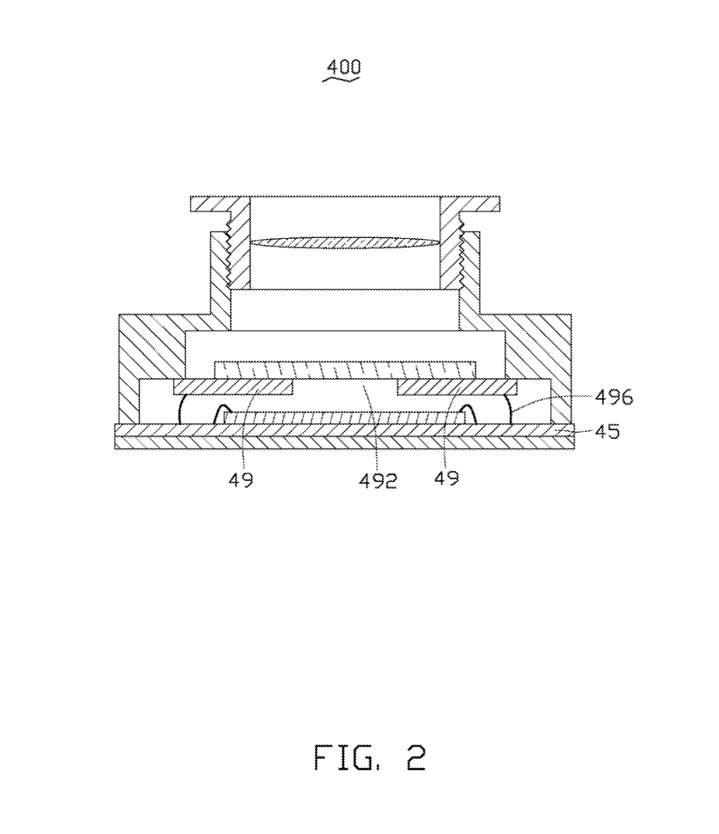

Referring to FIG. 2, a second embodiment of a camera module 400 differs from the first embodiment of the camera module only in that the camera module 400 includes two second circuit boards 49 electrically connected to the first circuit board 45 by wires 492. The two second circuit boards 49 are spaced apart to cooperatively define a gap 492 corresponding to the image sensor chip 47. The filter 51 interconnects the two second circuit boards 49.

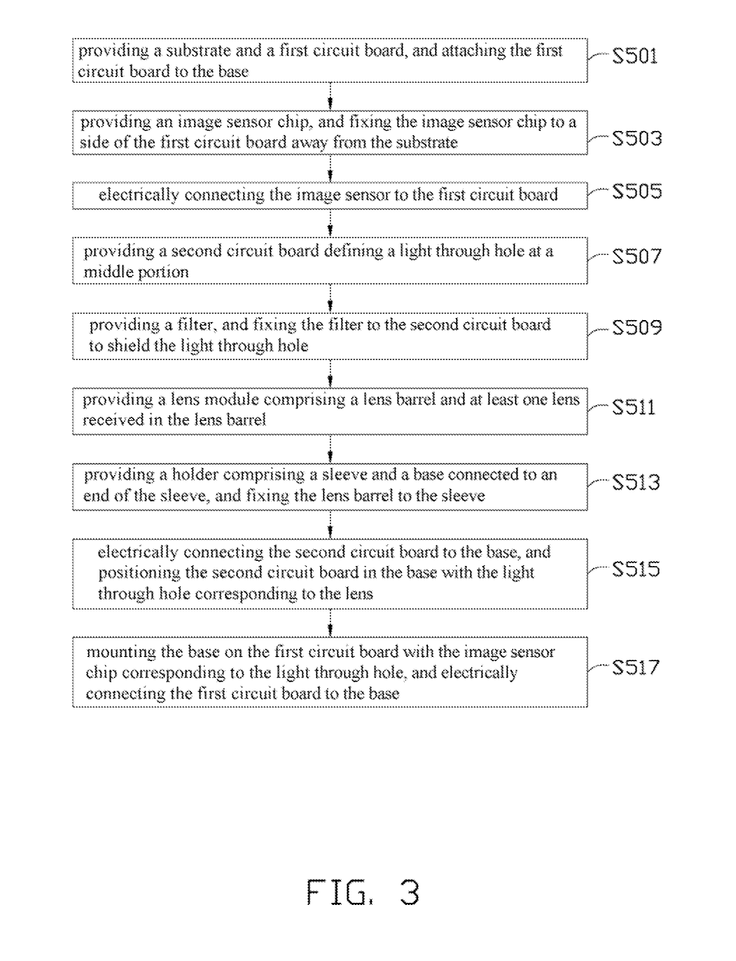

FIG. 3 shows a method of assembly for a camera module 100. The steps are not limited to the illustrated order and some steps may be performed simultaneously or partially simultaneously.

In step S501, a substrate 33 and a first circuit board 25 is provided, and the first circuit board 25 is attached to a side surface of the substrate 33. Electronic elements and integrated circuits of the camera module 200 are disposed on the first circuit board 25.

In step S503, an image sensor chip 27 is provided, and fixed to a side surface of the first circuit board 25 opposite to the substrate 33.

In step S505, the image sensor chip 27 is electrically connected to the first circuit board 25. In the illustrated embodiment, the image sensor chip 27 is connected to the first circuit board 25 by wires 272.

In step S507, a second circuit board 29 is provided, defining a light through hole 292 at a middle portion thereof. Other electronic elements and integrated circuits of the camera module 200 are disposed on the second circuit board 29.

In step S509, a filter 31 is provided, and fixed to the second circuit board 29. The filter 31 shields the light through hole 292.

In step S511, a lens module 23 is provided. The lens module 23 includes a lens barrel 231 and at least one lens 233 received in the lens barrel 231. The lens barrel 231 forms an external thread 2312 on the outer surface of the lens barrel 231.

In step S513, a holder 21 is provided. The holder 21 includes a sleeve 212 and a base 214 connected to an end of the sleeve 212. The sleeve 212 is a substantially hollow cylinder, and forms an internal thread 2121 thereof. The lens module 23 is threaded into the sleeve 212 of the holder 21.

In step S515, the second circuit board 29 is electrically connected to the base 214, and securely positioned in the base 214 with the light through hole 292 corresponding to the lens 233.

In step S517, the base 214 is mounted on the first circuit board 29 with the image sensor chip 27 corresponding to the light through hole 292. The first circuit board 29 is electrically connected to the base 214.

It is believed that the present embodiments and their advantages will be understood from the foregoing description, and it will be apparent that various changes may be made thereto without departing from the spirit and scope of the disclosure or sacrificing all of its material advantages.

What is claimed is:

1. A camera module, comprising:
a first circuit board;
a holder mounted on the first circuit board, wherein the holder comprises a sleeve and a base connected to an end of the sleeve, the base defining a first receiving portion;
a lens module received in the sleeve;
a image sensor chip electrically fixed to the first circuit board and received in the first receiving portion;
a filter received in the first receiving portion corresponding to the image sensor chip; and
a second circuit board electrically connected to the first circuit board, received in the first receiving portion, and fixed to the base, and incident light is capable of passing through the lens module and the filter in that order, and finally projecting on the image sensor.

2. The camera module of claim 1, wherein the first circuit board and the second circuit board are fixed to the base by conductive adhesive.

3. The camera module of claim 1, wherein the second circuit board is electrically connected to first circuit board by wires.

4. The camera module of claim 1, wherein the first circuit board and the second circuit board are at opposite sides of the image sensor, and the second circuit board defines a light through hole corresponding to the image sensor chip.

5. The camera module of claim 4, wherein the filter is fixed to the second circuit board and shields the light through hole.

6. The camera module of claim 5, wherein the base further defines a second receiving portion depressed from the bottom of the first receiving portion, the second receiving portion communicates between the first receiving portion and the sleeve, the first receiving portion and the second receiving portion cooperatively defines a fixing surface at a bottom of the first receiving portion adjacent to the second receiving portion, and the second circuit board is fixed to the fixing surface with the filter received in the second receiving portion.

7. The camera module of claim 1, further comprising two second circuit boards spaced apart and fixed to the base, and cooperatively defining a gap corresponding to the image sensor chip.

8. The camera module of claim 7, wherein the filter interconnects the two second circuit boards.

9. A method for assembling a camera module, comprising:
providing a substrate and a first circuit board, and attaching the first circuit board to the base;
providing an image sensor chip, and fixing the image sensor chip to a side of the first circuit board away from the substrate;
electrically connecting the image sensor to the first circuit board;
providing a second circuit board defining a light through hole at a middle portion;
providing a filter, and fixing the filter to the second circuit board to shield the light through hole;
providing a lens module comprising a lens barrel and at least one lens received in the lens barrel;
providing a holder comprising a sleeve and a base connected to an end of the sleeve, and fixing the lens barrel to the sleeve;
electrically connecting the second circuit board to the base, and securely receiving the second circuit board in the base with the light through hole corresponding to the lens; and
mounting the base on the first circuit board with the image sensor chip corresponding to the light through hole, and electrically connecting the first circuit board to the base.

10. The method of claim 9, wherein the first circuit board and the second circuit board are fixed to the base by conductive adhesive.

11. The method of claim 9, wherein the second circuit board is electrically connected to the first circuit board by wires.
